(19) United States
(12) Patent Application Publication
(10) Pub. No.: US 2011/0256653 A1
(43) Pub. Date: Oct. 20, 2011

(54) Thermoelectric Modules and Methods for Manufacturing Thermoelectric Modules

(75) Inventors: Gustavo Garcia Ramos, Vitoria-Gasteiz (ES); Francisco Javier Aranceta Aguirre, Abadino (ES); José Javier Borda Camino, Donostia-San Sebastian (ES); Antonio José Barbero Merino, Mondragon (ES)

(73) Assignee: MONDRAGON COMPONENTES, S.COOP., ARETXABALETA (Gipuzkoa) (ES)

(21) Appl. No.: 13/088,148

(22) Filed: Apr. 15, 2011

(30) Foreign Application Priority Data
Apr. 20, 2010 (EP) EP10382089

(51) Int. Cl. H01L 21/50

(52) U.S. Cl. 438/55; 257/E21.499

(57) ABSTRACT

A method for manufacturing a thermoelectric module that involves obtaining a first printed circuit board having a first dielectric layer sandwiched between a first metallic substrate and a first electrical conductive layer, obtaining a second printed circuit board that comprises a second dielectric layer sandwiched between a second metallic substrate and a second electrical conductive layer, and positioning a plurality of N-type and P-type thermoelectric elements having first ends and second ends between the first and second electrical conduction layers so that the first ends of the thermoelectric elements are situated on the first electrical conductive layer and the second ends of the thermoelectric elements are situated on the second electrical conductive layer and arranged to form an electrical circuit that alternates between the N-type and P-type thermoelectric elements.

### CROSS-REFERENCE TO RELATED APPLICATIONS

The present application relates to and claims the benefit of European Patent Application No. EP10382089, filed Apr. 20, 2010.

### TECHNICAL FIELD

The present invention relates to thermoelectric modules and methods for manufacturing thermoelectric modules.

### BACKGROUND

Thermoelectric modules are widely known in the prior art and are used largely to transmit heat from an object or surface to another object (refrigeration) by applying an electrical current to an electric conduction (Peltier effect), although they may also be used to obtain an electrical current from a difference in temperature between two objects (Seebeck effect).

Generally speaking, the modules comprise an electrically conductive layer, preferably copper, and a support substrate, generally alumina or another type of ceramic material. On the conductive layer are arranged in an alternating manner a plurality of N-type and P-type thermoelectric elements. The copper comprises a structure that corresponds with a required electric conduction for the module.

The drawback with using alumina or another type of ceramic material is that the module cannot be easily and quickly connected to the surface of the object to be refrigerated or from which the difference in temperature is to be obtained, as excessive attachment forces may cause the alumina and therefore the module to break. Similarly, the size of the module is restricted because the structure of the alumina cannot support large modules.

U.S. Pat. No. 5,040,381 discloses a module having a support substrate that can comprise aluminium or copper instead of alumina, thereby resolving the aforementioned drawbacks. The module is manufactured by disposing, in a laminated manner, a dielectric layer on the support substrate, with a copper plate of a certain thickness being arranged on the dielectric layer, and thermoelectric elements being arranged on the copper plate.

### SUMMARY OF THE DISCLOSURE

In a method for manufacturing a thermoelectric module of the invention, a plurality of thermoelectric elements are arranged on an electrically conductive layer, and the thermoelectric elements are connected to the conductive layer. The conductive layer forms part of a printed circuit board, the printed circuit board comprising the conductive layer, a metallic substrate and a dielectric layer arranged between the metallic substrate and the conductive layer, the purpose of the dielectric layer being to insulate the conductive and metallic substrates electrically from each other.

The conductive layer comprises a certain structure for the purposes of obtaining, together with the thermoelectric elements, a required electrical flow path.

Methods of the invention enable the manufacture of thermoelectric modules from a printed circuit board, thereby reducing the cost and time involved in manufacturing the module, and even making the manufacture far more flexible as the required circuit may be designed in a simple and quick manner, which can be especially advantageous in testing new designs or prototypes for their subsequent mass manufacture, for example.

These and other advantages and characteristics of the invention will be made evident in the light of the drawings and the detailed description thereof.

### BRIEF DESCRIPTION OF THE DRAWINGS

FIG. 1 shows an embodiment of a thermoelectric module.

FIG. 2 illustrates an electric flow path through the thermoelectric module of FIG. 1.

FIG. 3 is a ground view of a structure of a conductive layer of the thermoelectric module of FIG. 1, arranged on a dielectric layer of the module.

FIG. 4 shows a thermoelectric module according to another embodiment.

FIG. 5 shows a thermoelectric module according to another embodiment.

FIG. 6 shows a thermoelectric module according to another embodiment.

### DETAILED DESCRIPTION

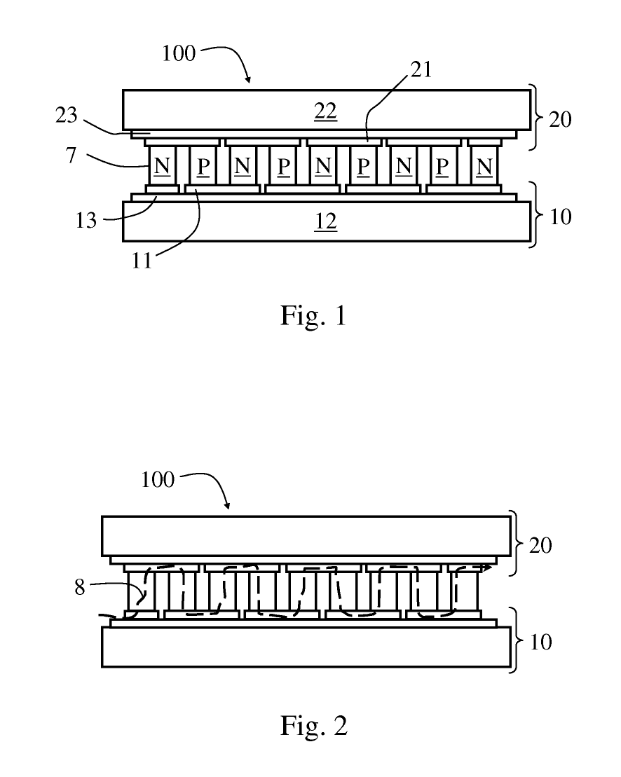

In a method of the invention, for manufacturing a thermoelectric module 100, a plurality of thermoelectric elements 7 are arranged on an electrically conductive layer 11, preferably copper, and the thermoelectric elements 7 are connected to the conductive layer 11 by means of, for example, conventional soldering. With reference to FIGS. 1 and 2, the conductive layer 11 forms part of a printed circuit board 10, the printed circuit board 10 comprising the conductive layer 11, a metallic substrate 12 and a dielectric layer 13 that is arranged between the metallic substrate 12 and the conductive layer 11 and which preferably corresponds with a commercial epoxy or resin, such as the one known as Thermal CLAD®, the conductive layer 11 being electrically insulated from the metallic substrate 12 by the dielectric layer.

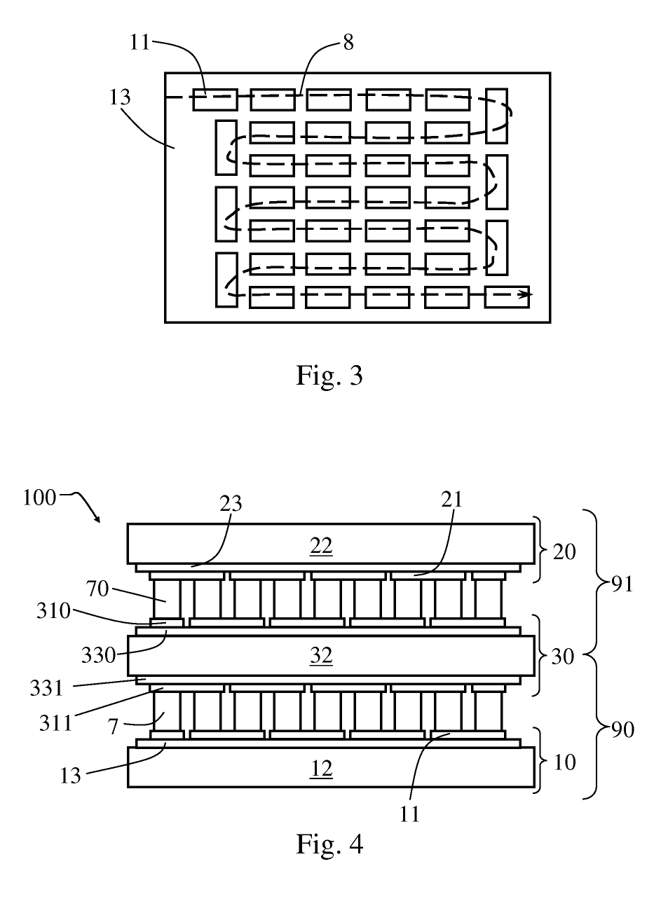

The conductive layer 11 may comprise a certain structure, such as the one shown for example in FIG. 3, the purpose being to obtain, together with the thermoelectric elements 7 an electric conduction flow path 8. The thermoelectric elements 7 are of the N-type and P-type, being arranged in an alternate manner as shown in FIG. 1.

Printed circuit boards generally comprise at least three layers: a substrate that is generally fibre glass, a conductive layer that is generally copper, and a dielectric layer arranged between the fibre glass and the conductive layer and which also ensures that the conductive layer adheres or fixes to the fibre glass. According to the present invention one or more pre-manufactured printed circuit boards are used in the construction of the thermoelectric modules, the pre-manufactured printed circuit boards having a metallic substrate rather than a fibre glass substrate. In one embodiment the metallic substrate of the printed circuit board is aluminium, although it can be made of another metal, preferably a metal having a thermal conductivity greater than the thermal conductivity of alumina. A metal with a lower thermal conductivity can be used although the performance and/or the efficiency of the module 100 may be reduced in this case, making the use of the modules 100 potentially unprofitable. As a result, the module 100 can be fixed to an object in a simple and quick manner as the strength provided by the metallic substrate means that it can be handled without fear of it breaking, as is the case when handling alumina. In addition, the use of printed circuit boards having a metallic support structure, such as, for example aluminium, allows thermoelectric modules to be manufactured in larger sizes due to the strength provided by the metallic substrate. Furthermore, the heat transfer characteristics of the metallic substrate (e.g. aluminium) results in a more efficient module 100.

According to one implementation a thermoelectric module is produced by obtaining a pre-manufactured printed circuit board such as printed circuit board 10 comprising a metallic substrate, a dielectric layer and a conductive layer devoid of electrical flow path traces. In such an implementation conductive paths are formed by selectively removing part of the conductive layer 11 from the printed circuit board 10 prior to the disposal of the thermoelectric elements 7 on the printed circuit board. Portions of the conductive layer 11 may be removed by using any known method, although any technique used in the manufacture of printed circuits (mechanical, chemical, laser, etc) is used. The thermoelectric elements 7, for their own, are arranged on the conductive layer 11, preferably by also using any technique used in the manufacture of electronic circuits, such as pick-and-place machines. The thermoelectric elements 7 can thus be fixed to the conductive layer 11 by means of conventional soldering, the module being introduced in an oven or equivalent appliance not shown in the figures.

According to other implementations, the conductive layer 11 of the printed circuit is patterned on the dielectric layer 13 using masking and deposition processes known in the art. In such implementations the need to remove portions of the conductive layer 11 is obviated and it is sufficient therefore to arrange the thermoelectric elements 7 on the conductive layer 11 without having to carry out an additional operation of removing part of the conductive layer 11.

By using a pre-manufactured printed circuit board 10 a thermoelectric module 100 may be manufactured in a simple and quick manner. The patterned structure of the conductive layer 11 can be achieved quickly by using known patterning techniques. Moreover, the complex and time-consuming operations traditionally involved in forming substrates/layers in thermoelectric modules is avoided by the use of pre-manufactured printed circuit boards. The methods of the invention thus enables the more flexible manufacture of thermoelectric modules 100, thereby facilitating, for example, the design and use of prototypes in a quick and simple manner. In addition, with the methods of the invention a compact module 100 can be obtained, given that different thermoelectric elements 7 can be arranged very close to each other due to the ease with which the patterned conductive layer 11 is obtained. Another advantage of using the methods of the invention is the ease with which modules 100 with different arrangements can be obtained due to the fact that thermoelectric elements 7 of different sizes and/or shapes can be arranged in a single module 100, in a very simple way.

According to some implementations a second printed circuit board 20 is arranged on the thermoelectric elements 7, the second printed circuit board 20 comprising a metallic substrate 22, an electrically conductive layer 21, and a dielectric layer 23 that is arranged between the metallic substrate 22 and the conductive layer 21 and which preferably corresponds with a commercial epoxy or resin, such as the one known as Thermal CLAD®, the conductive layer 21 being arranged on the thermoelectric elements 7 so that the thermoelectric elements 7 are arranged between the conductive layers 11 and 21 of printed circuit boards 10 and 20, respectively. As a result, a closed electrical conduction path 8 is provided as shown in FIG. 2. The two printed circuit boards 10 and 20, together with the thermoelectric elements 7, form a modular unit 90 that, in the embodiment of FIGS. 1 and 2, corresponds with a thermoelectric module 100.

According to another implementation, as shown in FIG. 4, a thermal module 100 is provided that comprises printed circuit boards 10 and 20 as described above, and an additional printed circuit board 30 situated between and electrically coupled to printed circuit boards 10 and 20 by thermoelectric elements 7 and 70, respectively. According to one implementation, printed circuit board 30 comprises respective dielectric layers 330, 331 and conductive layers 310, 311 situated on opposing sides of a single metallic substrate 32. Hereinafter, a printed circuit board comprising two conductive layers for the attachment of thermoelectric elements is identified as a double printed circuit board, whereas a printed circuit board comprising a single conductive layer for the attachment of thermoelectric elements is identified as a single printed circuit board.

As noted above, in the implementation of FIG. 4 the module 100 comprises two single printed circuit boards 10 and 20 and a double printed circuit board 30. Situated between single printed circuit 10 and double printed circuit board 30 are thermoelectric elements 7. The thermoelectric elements 7 are coupled to and sandwiched between the conductive layers 11 and 311 of printed circuit boards 10 and 30, respectively, to form a first modular unit 90. Situated between single printed circuit 20 and double printed circuit board 30 are thermoelectric elements 70. The thermoelectric elements 70 are coupled to and sandwiched between the conductive layers 21 and 310 of printed circuit boards 20 and 30, respectively, to form a second modular unit 91. The embodiment of FIG. 4 comprises two modular units 90 and 91 that share a common double printed circuit board. However, it is appreciated that the use of multiple double printed circuit boards may be used to form thermoelectric modules comprising more than two modular units.

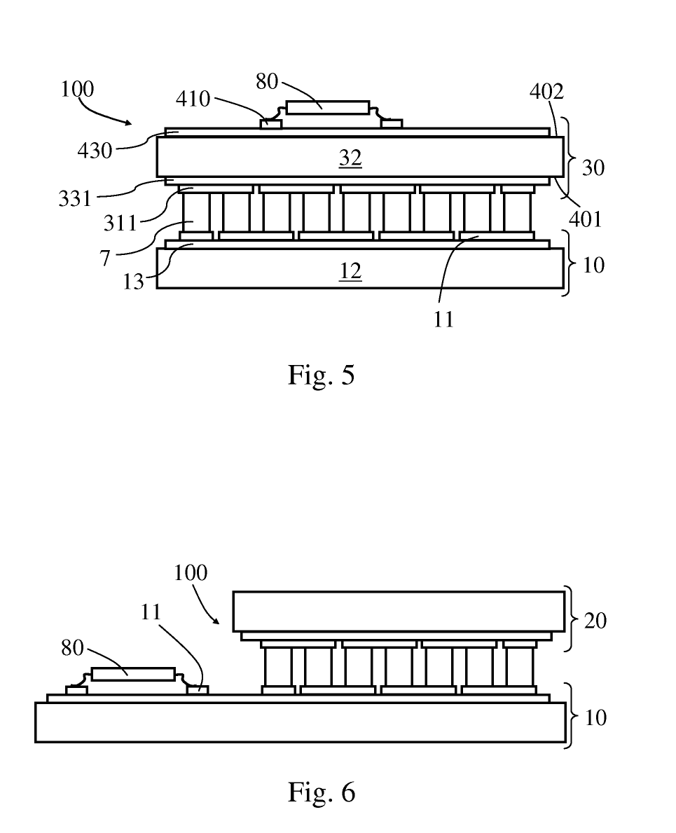

In the embodiment of FIG. 5, the thermoelectric module 100 comprises a single printed circuit board 10 and a double printed circuit board 30. The double printed circuit board 30 comprises a metallic substrate 32 having opposite facing surfaces 401 and 402. Surface 401 has situated thereon dielectric and conductive layers 331 and 311, respectively. Surface 402 has situated thereon dielectric and conductive layers 430 and 410, respectively. Thermoelectric elements 7 are coupled to and sandwiched between the conductive layers 11 and 311 of printed circuit boards 10 and 30, respectively. One or more electronic devices 80 is arranged on the conductive layer 410 for being directly and efficiently cooled. This arrangement can be achieved regardless of the number of modular units that make up the module 100.

According to another embodiment, as shown in FIG. 6, at least one of the printed circuit boards 10 may comprise a greater width and/or length than that necessary for the module 100, so that electronic devices 80 can be arranged in the additional width and/or length area. An advantage of this embodiment is the use of the module 100 to generate the Seebeck effect, so that the energy generated can be used to supply the electronic device 80. In addition, as the electronic device 80 is arranged on the same metallic substrate 12 as the module 100, the electronic circuitry 80 can make use of the heat transfer qualities of the module 100 to ensure sufficient cooling.

An additional advantage of the module 100 of the embodiments incorporating electronic devices 80 is that both the electronic device 80 and the elements of the module 100 can be connected to each other or soldered at the same time, in a single operation, by means of an oven or an equivalent appliance, thus making the assembly process easier. Furthermore, the module 100 and the one or more electronic devices 80 form a single compact and indivisible element.

What is claimed is:

1. A method for manufacturing a thermoelectric module comprising:
obtaining a first printed circuit board that comprises a first dielectric layer sandwiched between a first metallic substrate and a first electrical conductive layer;
obtaining a second printed circuit board that comprises a second dielectric layer sandwiched between a second metallic substrate and a second electrical conductive layer;
selectively removing at least a portion of the first electrical conductive layer to form a first set of electrical conduction flow paths;
selectively removing at least a portion of the second electrical conductive layer to form a second set of electrical conduction flow paths;
positioning a plurality of N-type and P-type thermoelectric elements having first ends and second ends between the first and second electrical conduction layers so that the first ends of the thermoelectric elements are situated on the first electrical conductive layer and the second ends of the thermoelectric elements are situated on the second electrical conductive layer, the first set of electrical conduction flow paths, second electrical conduction paths, N-type thermoelectric elements and P-type thermoelectric elements arranged to form an electrical circuit that alternates between the N-type and P-type thermoelectric elements.

2. A method according to claim 1, further comprising bonding the first and second ends of the thermoelectric elements to the first and second electrical conductive layer, respectively.

3. A method according to claim 2, wherein the first and second ends of the thermoelectric elements are bonded to the first and second electrical conductive layers by use of a solder.

4. A method according to claim 3, wherein the bonding occurs in an oven.

5. A method according to claim 1, wherein the first and second metallic substrates have a thermal conductivity greater than alumina.

6. A method according to claim 1, wherein the first and second metallic substrates possess sufficient strength to resist breakage during the manufacturing process.

7. A method according to claim 1, wherein the first and second metallic substrates have a thermal conductivity greater than alumina and possess sufficient strength to resist breakage during the manufacturing process.

8. A method for manufacturing a thermoelectric module comprising:
obtaining a first printed circuit board that comprises a first dielectric layer sandwiched between a first metallic substrate and a first electrical conductive layer, the first electrical conductive layer comprising a first set of electrical conduction flow paths;
obtaining a second printed circuit board that comprises a second dielectric layer sandwiched between a second metallic substrate and a second electrical conductive layer, the second electrical conductive layer comprising a second set of electrical conduction flow paths;
positioning a plurality of N-type and P-type thermoelectric elements having first ends and second ends between the first and second electrical conduction layers so that the first ends of the thermoelectric elements are situated on the first electrical conductive layer and the second ends of the thermoelectric elements are situated on the second electrical conductive layer, the first set of electrical conduction flow paths, the second electrical conduction paths, N-type thermoelectric elements and P-type thermoelectric elements arranged to form an electrical circuit that alternates between the N-type and P-type thermoelectric elements.

9. A method according to claim 8, further comprising bonding the first and second ends of the thermoelectric elements to the first and second electrical conductive layer, respectively.

10. A method according to claim 9, wherein the first and second ends of the thermoelectric elements are bonded to the first and second electrical conductive layers by use of a solder.

11. A method according to claim 10, wherein the bonding occurs in an oven.

12. A method according to claim 8, wherein the first and second metallic substrates have a thermal conductivity greater than alumina.

13. A method according to claim 8, wherein the first and second metallic substrates possess sufficient strength to resist breakage during the manufacturing process.

14. A method according to claim 8, wherein the first and second metallic substrates have a thermal conductivity greater than alumina and possess sufficient strength to resist breakage during the manufacturing process.

15. A method for manufacturing a thermoelectric module comprising:
obtaining a first printed circuit board that comprises a first dielectric layer sandwiched between a first metallic substrate and a first electrical conductive layer;
obtaining a second printed circuit board that comprises a second dielectric layer sandwiched between a second metallic substrate and a second electrical conductive layer;
obtaining a third printed circuit board that comprises a third metallic substrate having opposite facing first and second surfaces, a third dielectric layer sandwiched between the first surface and a third electrical conductive layer and a fourth dielectric layer sandwiched between the second surface and a fourth electrical conductive layer;
selectively removing at least a portion of the first electrical conductive layer to form a first set of electrical conduction flow paths;
selectively removing at least a portion of the second electrical conductive layer to form a second set of electrical conduction flow paths;
selectively removing at least a portion of the third electrical conductive layer to form a third set of electrical conduction flow paths;
selectively removing at least a portion of the fourth electrical conductive layer to form a fourth set of electrical conduction flow paths;
positioning a first plurality of N-type and P-type thermoelectric elements having first ends and second ends between the first and third electrical conduction layers so that the first ends of the thermoelectric elements are situated on the first electrical conductive layer and the second ends of the thermoelectric elements are situated on the third electrical conductive layer, the first set of electrical conduction flow paths, third set of electrical conduction paths and plurality of N-type and P-type thermoelectric elements arranged to forming an electrical circuit that alternates between the N-type and P-type thermoelectric elements; and
positioning a second plurality of N-type and P-type thermoelectric elements having first ends and second ends between the second and fourth electrical conduction layers so that the first ends of the thermoelectric elements are situated on the second electrical conductive layer and the second ends of the thermoelectric elements are situated on the fourth electrical conductive layer, the second set of electrical conduction flow paths, fourth set of electrical conduction paths and plurality of N-type and P-type thermoelectric elements arranged to form an electrical circuit that alternates between the N-type and P-type thermoelectric elements.

16. A method according to claim 15, further comprising bonding the first and second ends of the first plurality of thermoelectric elements to the first and third electrical conductive layer, respectively, and bonding the first and second ends of the second plurality of thermoelectric elements to the second and fourth electrical conductive layer, respectively.

17. A method according to claim 16, wherein the first and second ends of the thermoelectric elements are bonded to the first and second electrical conductive layers by use of a solder.

18. A method according to claim 17, wherein the bonding occurs in an oven.

19. A method according to claim 15, wherein the first, second and third metallic substrates have a thermal conductivity greater than alumina.

20. A method according to claim 15, wherein the first, second and third metallic substrates possess sufficient strength to resist breakage during the manufacturing process.

21. A method according to claim 15, wherein the first, second and third metallic substrates have a thermal conductivity greater than alumina and possess sufficient strength to resist breakage during the manufacturing process.

22. A method for manufacturing a thermoelectric module comprising:
obtaining a first printed circuit board that comprises a first dielectric layer sandwiched between a first metallic substrate and a first electrical conductive layer, the first electrical conductive layer comprising a first set of electrical conduction flow paths;
obtaining a second printed circuit board that comprises a second dielectric layer sandwiched between a second metallic substrate and a second electrical conductive layer, the second electrical conductive layer comprising a second set of electrical conduction flow paths;
obtaining a third printed circuit board that comprises a third metallic substrate having opposite facing first and second surfaces, a third dielectric layer sandwiched between the first surface and a third electrical conductive layer and a fourth dielectric layer sandwiched between the second surface and a fourth electrical conductive layer, the third electrical conductive layer comprising a third set of electrical conduction flow paths, the fourth electrical conductive layer comprising a fourth set of electrical conduction flow paths;
positioning a first plurality of N-type and P-type thermoelectric elements having first ends and second ends between the first and third electrical conduction layers so that the first ends of the thermoelectric elements are situated on the first electrical conductive layer and the second ends of the thermoelectric elements are situated on the third electrical conductive layer, the first set of electrical conduction flow paths, third set of electrical conduction paths and plurality of N-type and P-type thermoelectric elements arranged to forming an electrical circuit that alternates between the N-type and P-type thermoelectric elements; and
positioning a second plurality of N-type and P-type thermoelectric elements having first ends and second ends between the second and fourth electrical conduction layers so that the first ends of the thermoelectric elements are situated on the second electrical conductive layer and the second ends of the thermoelectric elements are situated on the fourth electrical conductive layer, the second set of electrical conduction flow paths, fourth set of electrical conduction paths and plurality of N-type and P-type thermoelectric elements arranged to form an electrical circuit that alternates between the N-type and P-type thermoelectric elements.

23. A method according to claim 22, further comprising bonding the first and second ends of the first plurality of thermoelectric elements to the first and third electrical conductive layer, respectively, and bonding the first and second ends of the second plurality of thermoelectric elements to the second and fourth electrical conductive layer, respectively.

24. A method according to claim 23, wherein the first and second ends of the thermoelectric elements are bonded to the first and second electrical conductive layers by use of a solder.

25. A method according to claim 24, wherein the bonding occurs in an oven.

26. A method according to claim 22, wherein the first, second and third metallic substrates have a thermal conductivity greater than alumina.

27. A method according to claim 22, wherein the first, second and third metallic substrates possess sufficient strength to resist breakage during the manufacturing process.

28. A method according to claim 22, wherein the first, second and third metallic substrates have a thermal conductivity greater than alumina and possess sufficient strength to resist breakage during the manufacturing process.

29. A method for manufacturing a thermoelectric module comprising:
obtaining a first printed circuit board that comprises a first dielectric layer sandwiched between a first metallic substrate and a first electrical conductive layer, the first electrical conductive layer comprising a first set of electrical conduction flow paths;
obtaining a second printed circuit board that comprises a second metallic substrate having opposite facing first and second surfaces, a second dielectric layer sandwiched between the first surface and a second electrical conductive layer and a third dielectric layer sandwiched between the second surface and a third electrical conductive layer, the second electrical conductive layer comprising a second set of electrical conduction flow paths, the third electrical conductive layer comprising a third set of electrical conduction flow paths;
positioning a plurality of N-type and P-type thermoelectric elements having first ends and second ends between the first and second electrical conduction layers so that the first ends of the thermoelectric elements are situated on the first electrical conductive layer and the second ends of the thermoelectric elements are situated on the second electrical conductive layer, the first set of electrical conduction flow paths, second set of electrical conduction paths, N-type thermoelectric elements and P-type thermoelectric elements arranged to form an electrical circuit that alternates between the N-type and P-type thermoelectric elements.

30. A method according to claim 29, further comprising coupling an electronic device to the third electrical conduction layer.

31. A method according to claim 29, wherein the first and second ends of the thermoelectric elements are bonded to the first and second electrical conductive layers by use of a solder.

32. A method according to claim 31, wherein the bonding occurs in an oven.

33. A method according to claim 29, wherein the first and second metallic substrates have a thermal conductivity greater than alumina.

34. A method according to claim 29, wherein the first and second metallic substrates possess sufficient strength to resist breakage during the manufacturing process.

35. A method according to claim 29, wherein the first and second metallic substrates have a thermal conductivity greater than alumina and possess sufficient strength to resist breakage during the manufacturing process.

36. A method for manufacturing a thermoelectric module comprising:
obtaining a first printed circuit board that comprises a first dielectric layer sandwiched between a first metallic substrate and a first electrical conductive layer, the first electrical conductive layer comprising a first set of electrical conduction flow paths;
obtaining a second printed circuit board that comprises a second metallic substrate having opposite facing first and second surfaces, a second dielectric layer sandwiched between the first surface and a second electrical conductive layer and a third dielectric layer sandwiched between the second surface and a third electrical conductive layer;
selectively removing at least a portion of the first electrical conductive layer to form a first set of electrical conduction flow paths;
selectively removing at least a portion of the second electrical conductive layer to form a second set of electrical conduction flow paths;
selectively removing at least a portion of the third electrical conductive layer to form a third set of electrical conduction flow paths; and
positioning a plurality of N-type and P-type thermoelectric elements having first ends and second ends between the first and second electrical conduction layers so that the first ends of the thermoelectric elements are situated on the first electrical conductive layer and the second ends of the thermoelectric elements are situated on the second electrical conductive layer, the first set of electrical conduction flow paths, second electrical conduction paths, N-type thermoelectric elements and P-type thermoelectric elements arranged to form an electrical circuit that alternates between the N-type and P-type thermoelectric elements.

37. A method according to claim 36, further comprising coupling an electronic device to the third electrical conduction layer.

38. A method according to claim 36, wherein the first and second ends of the thermoelectric elements are bonded to the first and second electrical conductive layers by use of a solder.

39. A method according to claim 38, wherein the bonding occurs in an oven.

40. A method according to claim 36, wherein the first and second metallic substrates have a thermal conductivity greater than alumina.

41. A method according to claim 36, wherein the first and second metallic substrates possess sufficient strength to resist breakage during the manufacturing process.

42. A method according to claim 36, wherein the first and second metallic substrates have a thermal conductivity greater than alumina and possess sufficient strength to resist breakage during the manufacturing process.
